(19) United States
(12) Patent Application Publication
(10) Pub. No.: US 2025/0063855 A1
(43) Pub. Date: Feb. 20, 2025

(54) METHOD FOR PREPARING AND BONDING WAFER-LEVEL CHIP USED IN MICRO-LED

(71) Applicant: Shanghai University, Shanghai (CN)

(72) Inventors: Jianhua Zhang, Shanghai (CN); Luqiao Yin, Shanghai (CN); Xiaoxiao Mu, Shanghai (CN); Haojie Zhou, Shanghai (CN)

(21) Appl. No.: 18/802,000

(22) Filed: Aug. 13, 2024

(30) Foreign Application Priority Data
Aug. 18, 2023 (CN) 2023110488631

(51) Int. Cl. H01L 33/00; H01L 33/36

(52) U.S. Cl. CPC H01L 33/0093; H01L 33/0075; H01L 33/36; H01L 2933/0016

(57) ABSTRACT

A method for preparing and bonding a wafer-level chip used in micro light emitting diode (Micro-LED) includes: exposing pixel areas on a complementary metal oxide semiconductor (CMOS) driving substrate; patterning and growing metal electrodes; depositing a silicon dioxide (SiO₂) insulation layer; bonding a Micro-LED chip; striping a substrate of the Micro-LED chip; preparing Micro-LED pixels; corroding splashed ITO and a metal on side walls of the Micro-LED pixels; preparing a co-negative electrode in the Micro-LED pixels. The method adopts a wafer bonding, which eliminates needs for alignment during bonding and compensates for the accuracy issue of die-to-die alignment. Before bonding, a metallization and passivation layer protection are applied to the CMOS surface to reduce chemical damage to the pixels and the CMOS. Compared to wafer-to-wafer, it reduces the bonding contact surface area, reduces stress during bonding, and improves bonding yield.

### TECHNICAL FIELD

The disclosure relates to the technical field of display, and particularly to a method for preparing and bonding a wafer-level chip used in micro light emitting diode (Micro-LED).

### BACKGROUND

In the past decade, the display technology has developed rapidly and is widely used in television, computers, large billboards and small intelligent devices. Liquid crystal displays (LCD) and organic light emitting diode (OLED) displays have been widely used. But with the emerging display applications of virtual reality (VR) and augmented reality (AR), higher requirements have been put forward for the current mainstream displays. Micro-LED displays are mainly based on the third-generation semiconductor material gallium nitride (GaN), which have excellent characteristics such as high resolution, high brightness, low energy consumption, fast response, high contrast, and long lifespan, and are hailed as the ultimate display technology of the future.

To achieve display, it is necessary to integrate a Micro-LED chip with a CMOS driving substrate. At present, integrated technologies mainly include the following: wire bonding, adhesive bonding, microtube bonding, flip chip bonding, and wafer bonding. Although there are many bonding methods, most of them still cannot meet market requirements for high-resolution displays. For example, alloy wires of the wire bonding occupy more space, the adhesive bonding is only applicable for devices with pixel spacing greater than 100 micrometers (μm), the microtube bonding has not been applied in practice, although the flip chip bonding is gradually moving towards the goal of high resolution, the alignment accuracy and bonding yield issues during the bonding process still cannot be solved. The wafer bonding process does not require alignment, reducing the difficulty of the bonding process and achieving high-resolution display. However, higher requirements are placed on epitaxial growth and semiconductor processes.

The current bonding methods mainly rely on two bonding methods: die-to-die and wafer-to-wafer. The die-to-die requires high-precision alignment requirements, and the current chip structure makes substrate removal difficult. Traditional wafer-to-wafer bonding has a large contact area, which can lead to significant warping due to differences in material thermal expansion coefficients. In subsequent etching of individual pixels, high aspect ratio process requirements are required, resulting in low bonding yield and poor product consistency.

### SUMMARY

A method for preparing and bonding a wafer-level chip used in micro light emitting diode (Micro-LED) is provided, which is aimed to reduce the accuracy requirements of bonding alignment and achieve high-resolution Micro-LED display without affecting bonding strength and stability.

In order to achieve above purposes, the method for preparing and bonding a wafer-level chip used in Micro-LED includes the following steps.

Step 1, a negative photoresist is spin coated on a complementary metal oxide semiconductor (CMOS) driving substrate to form a first photoresist layer on the CMOS driving substrate, and the first photoresist layer and the CMOS driving substrate are processed by using a photolithography process to expose pixel areas on the CMOS driving substrate.

Step 2, metal electrodes are patterned and grown on the pixel areas, and the first photoresist layer and a metal on the first photoresist layer are removed.

Step 3, a silicon dioxide (SiO₂) insulation layer is deposited on the metal electrodes and a part of the CMOS driving substrate not covered by the metal electrodes, and a positive photoresist is spin coated on the SiO₂ insulation layer to form a second photoresist layer on the SiO₂ insulation layer. A part of the SiO₂ insulation layer on the metal electrodes is etched, followed by removing the second photoresist layer to obtain a first structure.

Step 4, a Micro-LED chip is bonded with the first structure by using a bonding process.

Step 5, a substrate of the Micro-LED chip after the bonding process is stripped off to expose a GaN layer of the Micro-LED chip.

Step 6, the positive photoresist is spin coated on the GaN layer of the Micro-LED chip to form a third photoresist layer on the GaN layer of the Micro LED chip, after exposure, the GaN layer, an ITO layer and a metal layer are etched to prepare Micro-LED pixels.

Step 7, splashed ITO and a splashed metal on side walls of the Micro-LED pixels are corroded, and then the third photoresist layer is removed.

Step 8, an insulation layer is deposited on the Micro-LED pixels and a part of the SiO₂ insulation layer not covered by the Micro-LED pixels by using a composition process, a part of a GaN layer of each Micro-LED pixel and a bonded metal layer of an outer ring cathode of the CMOS driving substrate are exposed, and unexposed parts of the GaN layers of the Micro-LED pixels, the side walls of the Micro-LED pixels and the part of the SiO₂ insulation layer not covered by the Micro-LED pixels are covered by the insulation layer.

Step 9, a co-negative electrode is prepared by using a composition process, and the co-negative electrode is connected with the bonded metal layer on the outer ring cathode of the CMOS driving substrate.

In an embodiment, a method of patterning and growing the metal electrodes on the pixel areas in step 2 includes one selected from the group consisting of sputter, E-beam, plating and chemical plating.

In an embodiment, a method of depositing the SiO₂ insulation layer in step 3 includes plasma-enhanced chemical vapor deposition.

In an embodiment, a bonding temperature of the bonding process in step 4 is a range of 150° C.-500° C., a bonding pressure of the bonding process in step 4 is a range of 1 newton (N) to 10 kilo newton (KN), and a time of the bonding process in step 4 is a range of 1 second(s) to 60 minutes (min).

In an embodiment, the substrate of the Micro-LED chip is stripped off by a laser or a chemical method in step 5.

In an embodiment, the etching in step 6 is dry etching, the GaN layer is etched by using chlorine (Cl₂) and boron trichloride (BCl₃) gas; the ITO layer and the metal layer are etched by using carbon tetrafluoride (CF₄) gas.

In an embodiment, a corrosive liquid utilized in the corroding of step 7 is aqua regia.

In an embodiment, a material made of the insulation layer in step 8 is at least one selected from the group consisting of silicon nitride, silicon oxide, and silicon oxynitride, and a thickness of the insulation layer is a range of 1 micron meter (μm)-10 μm.

Technical effects of the disclosure are as follows.

On the basis of wafer bonding, the disclosure performs the metal patterning on the CMOS driving substrate in advance, reducing the step of etching a metal layer during LED pixel isolation, and retaining the advantage of no alignment. The patterned metal during the bonding can release stress problems caused by different thermal expansion coefficients.

The disclosure adopts the wafer bonding, which eliminates the need for alignment during the bonding and compensates for the alignment accuracy issue during die-to-die bonding. The disclosure provides metallization and passivation layer protection on the surface of the CMOS driving substrate before the bonding, reducing subsequent etching processes for the pixel isolation and reducing chemical damage to the pixel and the CMOS driving substrate. Compared to a traditional wafer-to-wafer form of surface to surface bonding, the disclosure reduces the bonding contact area, resulting in smaller warpage. Additionally, silicon oxide and patterned metals can reduce bonding stress and improve bonding yield. Effectively reducing stress during bonding and improving bonding yield.

### BRIEF DESCRIPTION OF DRAWINGS

The accompanying drawings forming a part of the disclosure are used to provide a further understanding of the disclosure. The illustrative embodiments and explanations of the disclosure are used to explain the disclosure and do not constitute an improper limitation of the disclosure.

FIG. 1 is a cross-sectional structure diagram of a wafer bonded Micro-LED display substrate used in an embodiment of the disclosure.

FIG. 2 is a cross-sectional structure diagram of a CMOS driving substrate, metal electrodes, and a silicon dioxide (SiO₂) insulation layer in the embodiment of the disclosure.

FIG. 3 is a cross-sectional structure diagram of a bonding between a wafer Micro-LED chip and the CMOS driving substrate in the embodiment of the disclosure.

FIG. 4 is a cross-sectional structure diagram of a Micro-LED chip stripped a substrate in the embodiment of the disclosure.

FIG. 5 is a cross-sectional structure diagram of prepared Micro-LED pixels in the embodiment of the disclosure.

FIG. 6 is a cross-sectional structure diagram of deposited silicon oxide/(distributed Bragg reflection) DBR in the embodiment of the disclosure.

Description of reference numerals: 100. CMOS driving substrate; 200. SiO₂ insulation layer; 300. metal electrodes; 400. Micro-LED chip; 401. substrate of Micro-LED chip; 402. GaN layer; 403. ITO layer; 404. metal layer; 500. insulation layer; 600. co-negative electrode.

### DETAILED DESCRIPTION OF EMBODIMENTS

It should be noted that in the absence of conflicts, the embodiments and the features in the embodiments in the disclosure can be combined with each other. The disclosure will be explained in detail below with reference to the accompanying drawings and in conjunction with embodiments.

### Embodiment 1

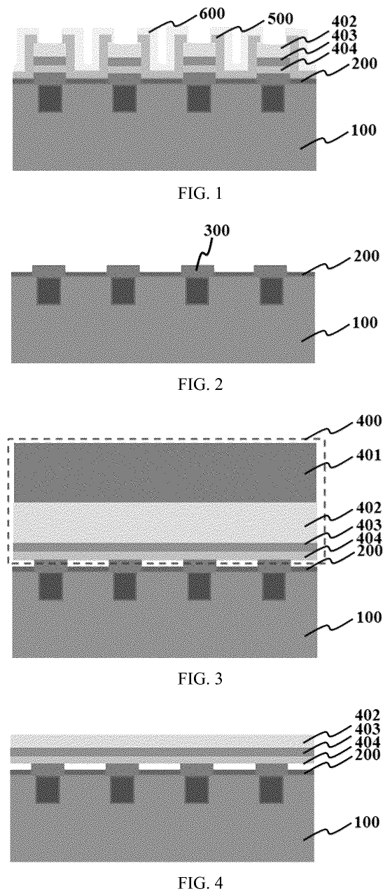

As shown in FIGS. 1-6, the embodiment provides a method for preparing and bonding a wafer-level chip used in Micro-LED, and the following steps are as follows.

Step 101, a negative photoresist is spin coated on a CMOS driving substrate 100 to form a first photoresist layer on the CMOS driving substrate 100, and the first photoresist layer and the CMOS driving substrate 100 are processed by using a photolithography process to expose pixel areas on the CMOS driving substrate. After the photolithography process, metal electrodes 300 (i.e., lower bonding metal layer) on the exposed pixel areas are sputtered.

Step 102, the metal electrodes 300 are patterned and grown on the pixel areas by a method of sputter, E-beam, plating or chemical plating, and the first photoresist layer and a metal on the first photoresist layer are removed by the stripping.

Step 103, after the first photoresist layer and the metal on the first photoresist layer are removed, a SiO₂ insulation layer 200 is deposited on the metal electrodes 300 and a part of the CMOS driving substrate 100 not covered by the metal electrodes 300 by using plasma-enhanced chemical vapor deposition (PECVD), and a positive photoresist is spin coated on the SiO₂ insulation layer 200 to form a second photoresist layer on the SiO₂ insulation layer 200. A part of the SiO₂ insulation layer 200 on the metal electrodes 300 is etched, followed by removing the second photoresist layer to obtain a first structure. As shown in FIG. 2.

Step 104, a Micro-LED chip 400 is bonded with the first structure by using a bonding process, as shown in FIG. 3. And a bonding temperature of the bonding process is a range of 150° C.-500° C., a bonding pressure of the bonding process is a range of 1 newton (N) to 10 kilo newton (KN), and a time of the bonding process is a range of 1 second(s) to 60 minutes (min).

Step 105, after the bonding process, a substrate 401 of the Micro-LED chip 401 is stripped off by a laser or a chemical method to expose a GaN layer 402 (i.e., chip epitaxial layer) of the Micro-LED chip 400, as shown in FIG. 4.

Step 106, the positive photoresist is spin coated on the GaN layer 402 of the Micro-LED chip 400 to form a third photoresist layer on the GaN layer 402 of the Micro LED chip 400, after exposure, the GaN layer 402, an ITO layer 403 (i.e., current spreading layer) and a metal layer 404 (i.e., upper bonding metal layer) are etched to prepare Micro-LED pixels. When the etching is dry etching, the GaN layer 402 is etched by using chlorine (Cl₂) and boron trichloride (BCl₃) gas; the ITO layer 403 and the metal layer 404 are etched by using carbon tetrafluoride (CF₄) gas, as shown in FIG. 5.

Step 107, splashed ITO and a splashed metal on side walls of the Micro-LED pixels are corroded with aqua regia, which is aimed to reduce leakage, and then the third photoresist layer is removed.

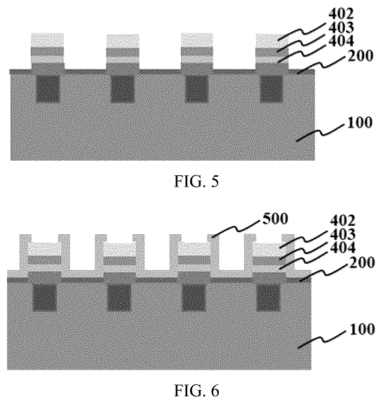

Step 108, an insulation layer 500 is deposited on the Micro-LED pixels and a part of the SiO₂ insulation layer 200 not covered by the Micro-LED pixels by using a composition process, a part of a GaN layer of each Micro-LED pixel and a bonded metal layer of an outer ring cathode of the CMOS driving substrate 100 are exposed, and unexposed parts of the GaN layers of the Micro-LED pixels, the side walls of the Micro-LED pixels and the part of the SiO₂ insulation in layer 100 not covered by the Micro-LED pixels are covered by the insulation layer 500 to avoid leakage caused by contact between the Micro-LED chip and the insulation layer. The material made of the insulation layer 500 is one or more selected from the group consisting of silicon nitride, silicon oxide, and silicon oxynitride, and a thickness of the insulation layer 500 is a range of 1 micron meter (μm)-10 μm, as shown in FIG. 6.

Step 109, a co-negative electrode 600 is prepared by using a composition process, and the co-negative electrode 600 is connected with the bonded metal layer on the outer ring cathode of the CMOS driving substrate 100, as shown in FIG. 1.

It should be noted that the composition process includes thin film deposition, photoresist coating, lithography, development, dry etching, chemical etching, photoresist removal, and metal stripping.

The above is only the preferred specific embodiment of the disclosure, but the scope of protection of the disclosure is not limited to this. Any change or replacement that can be easily thought of by those skilled in the art within the technical scope disclosed in the disclosure should be covered by the disclosure. Therefore, the protection scope of the disclosure should be based on the protection scope of the claims.

What is claimed is:

1. A method for preparing and bonding a wafer-level chip used in micro light emitting diode (Micro-LED), comprising:
step 1, spin coating a negative photoresist on a complementary metal oxide semiconductor (CMOS) driving substrate to form a first photoresist layer on the CMOS driving substrate, and processing the first photoresist layer and the CMOS driving substrate by using a photolithography process to expose pixel areas on the CMOS driving substrate;
step 2, patterning and growing metal electrodes on the pixel areas, and removing the first photoresist layer and a metal on the first photoresist layer;
step 3, depositing a silicon dioxide (SiO₂) insulation layer on the metal electrodes and a part of the CMOS driving substrate not covered by the metal electrodes, and spin coating a positive photoresist on the SiO₂ insulation layer to form a second photoresist layer on the SiO₂ insulation layer; etching a part of the SiO₂ insulation layer on the metal electrodes, following by removing the second photoresist layer to obtain a first structure;
step 4, bonding a Micro-LED chip with the first structure by using a bonding process;
step 5, striping off a substrate of the Micro-LED chip after the bonding to expose a GaN layer of the Micro-LED chip;
step 6, spin coating a positive photoresist on the GaN layer of the Micro-LED chip to form a third photoresist layer on the GaN layer of the Micro LED chip, and etching the GaN layer, a ITO layer and a metal layer after exposure to prepare Micro-LED pixels;
step 7, corroding splashed ITO and a splashed metal on side walls of the Micro-LED pixels, and then removing the third photoresist layer;
step 8, depositing, by using a composition process, an insulation layer on the Micro-LED pixels and a part of the SiO₂ insulation layer not covered by the Micro-LED pixels, exposing a part of a GaN layer of each Micro-LED pixel and a bonded metal layer of an outer ring cathode of the CMOS driving substrate, and covering unexposed parts of the GaN layers of the Micro-LED pixels, the side walls of the Micro-LED pixels and the part of the SiO₂ insulation layer not covered by the Micro-LED pixels;
step 9, preparing a co-negative electrode by using a composition process, and the co-negative electrode being connected with the bonded metal layer of the outer ring cathode of the CMOS driving substrate.

2. The method for preparing and bonding the wafer-level chip used in Micro-LED as claimed in claim 1, wherein a method of patterning and growing the metal electrodes on the pixel areas in step 2 comprises one selected from the group consisting of sputter, E-beam, plating and chemical plating.

3. The method for preparing and bonding the wafer-level chip used in Micro-LED as claimed in claim 1, a method of depositing the SiO₂ insulation layer in step 3 comprises plasma-enhanced chemical vapor deposition.

4. The method for preparing and bonding the wafer-level chip used in Micro-LED as claimed in claim 1, wherein a bonding temperature of the bonding process in step 4 is a range of 150° C.-500° C., a bonding pressure of the bonding process in step 4 is a range of 1 newton (N) to 10 kilo newton (KN), and a time of the bonding process in step 4 is a range of 1 second(s) to 60 minutes (min).

5. The method for preparing and bonding the wafer-level chip used in Micro-LED as claimed in claim 1, wherein the substrate of the Micro-LED chip is stripped off by a laser or a chemical method in step 5.

6. The method for preparing and bonding the wafer-level chip used in Micro-LED as claimed in claim 1, wherein the etching in step 6 is dry etching, the GaN layer is etched by using chlorine (Cl₂) and boron trichloride (BCl₃) gas; the ITO layer and the metal layer are etched by using carbon tetrafluoride (CF₄) gas.

7. The method for preparing and bonding the wafer-level chip used in Micro-LED as claimed in claim 1, wherein a corrosive liquid utilized in the corroding of step 7 is aqua regia.

8. The method for preparing and bonding the wafer-level chip used in Micro-LED as claimed in claim 1, wherein a material made of the insulation layer in step 8 is at least one selected from the group consisting of silicon nitride, silicon oxide, and silicon oxynitride, and a thickness of the insulation layer is a range of 1 micron meter (μm)-10 μm.
